(19) United States
(12) Patent Application Publication
(10) Pub. No.: US 2026/0144009 A1
(43) Pub. Date: May 21, 2026

(54) PIN LIFT HARD STOP

(71) Applicant: LAM RESEARCH CORPORATION, Fremont, CA (US)

(72) Inventors: Bryan Anthony CMELAK, King City, OR (US); Kevin BERTSCH, Tigard, OR (US); Jacob L. HIESTER, Newberg, OR (US); Sreeram SONTI, San Diego, CA (US)

(21) Appl. No.: 18/704,204

(22) PCT Filed: Oct. 31, 2022
(86) PCT No.: PCT/US2022/048466

§ 371 Date: Apr. 24, 2024

Related U.S. Application Data
(60) Provisional application No. 63/274,892, filed on Nov. 2, 2021.

(51) Int. Cl. H10P 72/76; C23C 16/458

(52) U.S. Cl. CPC H10P 72/7612; C23C 16/4586

(57) ABSTRACT

A hard stop for a substrate processing system includes: a first portion including: bosses configured to extend into first apertures in a lower bellows of a pin actuator; second apertures extending through the bosses, respectively, and the first portion; and a second portion including: a first end that is connected to the first portion; and a second end configured to contact a bracket of the pin actuator, the bracket configured to mount the pin actuator to a substrate processing chamber.

### CROSS-REFERENCE TO RELATED APPLICATIONS

This application claims the benefit of U.S. Provisional Application No. 63/274,892, filed on Nov. 2, 2021. The entire disclosure of the application referenced above is incorporated herein by reference.

### FIELD

The present disclosure relates to pin lifters of substrate processing systems and more particularly to hard stops of pin lifters.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, photoresist removal, etc. During processing, the substrate is arranged on a substrate support such as an electrostatic chuck and one or more process gases may be introduced into the processing chamber.

The one or more process gases may be delivered by a gas delivery system to the processing chamber. In some systems, the gas delivery system includes a manifold connected by one or more conduits to a showerhead that is located in the processing chamber. In some examples, deposition processes such as chemical vapor deposition (CVD), plasma enhanced CVD (PECVD), atomic layer deposition (ALD), etc. are used to deposit material on a substrate.

### SUMMARY

In a feature, a hard stop for a substrate processing system is described. The hard stop includes: a first portion including: bosses configured to extend into first apertures in a lower bellows of a pin actuator; second apertures extending through the bosses, respectively, and the first portion; and a second portion including: a first end that is connected to the first portion; and a second end configured to contact a bracket of the pin actuator, the bracket configured to mount the pin actuator to a substrate processing chamber.

In further features: the bosses include two bosses; and the second apertures include two second apertures extending through the two bosses, respectively, and the first portion.

In further features, the first and second portions are made of stainless steel.

In further features, the first and second portions are made of 17-4 PH stainless steel.

In further features, the 17-4 PH stainless steel is annealed.

In further features, a concave portion extends through the first and second portions, the concave portion configured to directly contact a cylindrical surface of the lower bellows of the pin actuator.

In further features, the second end of the second portion is rounded.

In a feature, a pin actuator for a substrate processing system is described. The pin actuator includes: a lead screw configured to: linearly move a pillow block in a first direction in response to rotation of the lead screw in the first direction; and linearly move the pillow block in a second direction that is opposite the first direction in response to rotation of the lead screw in the second direction; the pillow block; a lower bellows including apertures; a hard stop including bosses that extend into the apertures in the lower bellows; and fasteners that fasten the hard stop and the lower bellows to the pillow block.

In further features, a bracket is configured to mount the pin actuator to a substrate processing chamber, where the hard stop is disposed to contact a surface of the bracket.

In further features, the bracket includes: a first portion, where a track within which the pillow block moves is coupled to the first portion; and a second portion that is perpendicular to the first portion and that is to mount the pin actuator to the substrate processing chamber.

In further features, a shaft is coupled at a first end to the lower bellows and configured to couple at a second end to a pin ring, the pin ring configured to vertically raise and lower a substrate within the substrate processing chamber via pins of the pin ring.

In further features, a folded bellows surrounds the shaft.

In further features, the shaft extends through an aperture in the second portion of the bracket.

In further features, the hard stop includes a rounded edge configured to contact the surface of the bracket.

In further features: the lower bellows includes a cylindrical outer surface; and the hard stop includes a concave portion that directly contacts the cylindrical outer surface of the lower bellows.

In a feature, a substrate processing system includes: a processing chamber; a substrate support within the processing chamber, the substrate support to support substrates on an upper surface thereof; a pin ring including at least three pins that extend through apertures through the substrate support, the pins configured to vertically lower a substrate onto the upper surface of the substrate support and to vertically raise the substrate above the upper surface of the substrate support; a pin actuator configured to vertically raise and lower the pin ring, thereby vertically raising and lowering the at least three pins, respectively; a bracket configured to mount the pin actuator to the processing chamber; and a hard stop including bosses that extend into apertures in the pin actuator and that is mounted to the pin actuator, the hard stop configured to contact a surface of the bracket and limit a vertical height of the at least three pins relative to the substrate support to a maximum height.

In further features, the pin actuator includes: a lead screw configured to:
linearly move a pillow block in a first direction in response to rotation of the lead screw in the first direction; and linearly move the pillow block in a second direction that is opposite the first direction in response to rotation of the lead screw in the second direction; the pillow block; a lower bellows including the apertures; and fasteners that fasten the hard stop and the lower bellows to the pillow block.

In further features, the hard stop incudes: a first portion including: the bosses; second apertures through the bosses, respectively, and the first portion; and a second portion including: a first end that is connected to the first portion; and a second end configured to contact the surface of the bracket.

In further features, the hard stop further includes a concave portion that extends through the first and second portions, the concave portion directly contacting a cylindrical surface of the pin actuator.

In further features, the second end of the second portion is rounded.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIGS. 1 and 2 are functional block diagrams of an example of a substrate processing system;

FIG. 3 is a perspective view of an example implementation of a pin actuator;

FIG. 4 is a cross-sectional view of an example implementation of the pin actuator;

FIG. 5 is a perspective view of an example implementation of a hard stop;

FIG. 6 is a top view toward an inner portion of the hard stop;

FIG. 7 is a cross-sectional view taken along line A-A of FIG. 6;

FIG. 8 is a side view of the hard stop;

FIG. 9 is an end view of the hard stop;

FIG. 10 includes a top perspective view of an example implementation of the pin ring without the pins;

FIG. 11 includes a bottom perspective view of the example implementation of the pin ring without the pins; and

FIG. 12 is a perspective view including an example implementation of a processing chamber for multiple substrate supports and pin rings with pins.

In the drawings, reference numbers may be reused to identify similar and/or identical elements.

### DETAILED DESCRIPTION

Hard stops impose motion limitations on automation components by causing physical contact with a neighboring component when a position limit is reached. Hard stops may be used to prevent the position limit from being exceeded. Hard stops may also be used for position calibration, such as to identify limits of possible motion.

In substrate processing systems, a pin actuator may vertically raise and lower pins of a pin ring. The pin actuator may raise the pins, for example, to facilitate picking or placing of a substrate from or to a substrate support, which may also be referred to as a pedestal. The pin actuator may lower the pins, for example, for performance of one or more processes on the substrate, such as deposition of an ashable hard mask (AHM) on the substrate.

The substrate support may be raisable and lowerable to vary a distance between the substrate support and a showerhead. Different distances may be used, for example, for different substrate processes and/or to vary one or more characteristics during performance of one process.

The present application involves a hard stop of the pin actuator that contacts a bracket used to mount the pin actuator to a substrate processing chamber. The hard stop contacts the bracket when a vertical height of the pins reaches a vertical height limit. When the hard stop contacts the bracket, a controller stops a motor from attempting to further increase the vertical height of the pins. The hard stop prevents the pins from contacting the showerhead of the substrate processing chamber and prevents the pin ring from contacting a bottom surface of the substrate support.

The hard stop described herein does not require a change in the configuration of the pin actuator. The hard stop also allows for performance of processes using both (a) a narrow gap where the distance between the showerhead and the substrate support is a first distance and (b) a wide gap where the distance between the showerhead and the substrate support is a second distance that is greater than the first distance.

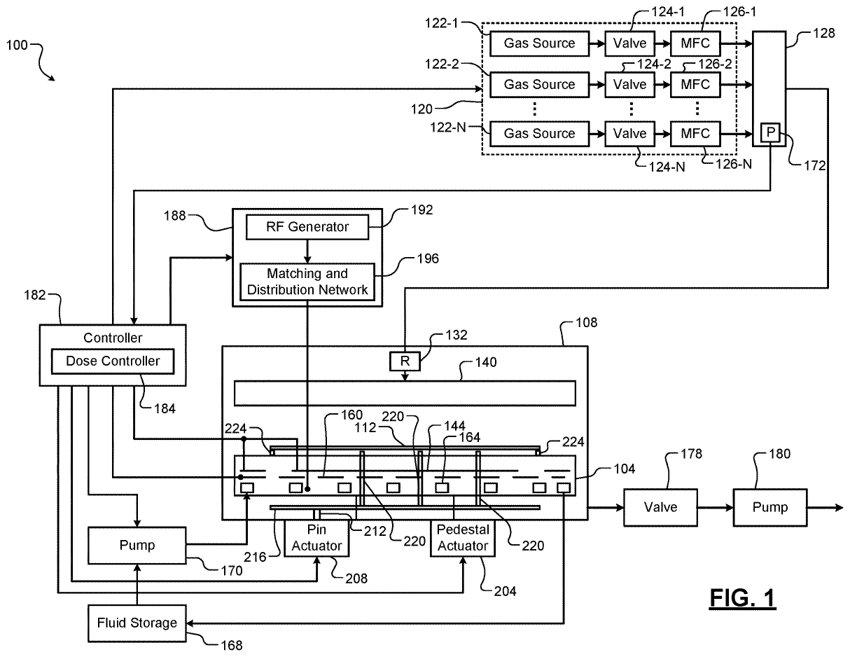

Referring now to FIG. 1, an example of a substrate processing system 100 including a substrate support (e.g., a pedestal) 104 according to the present disclosure is shown. The substrate support 104 is arranged within a processing chamber 108. A substrate 112 is arranged on the substrate support 104 during processing.

A gas delivery system 120 includes gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126), respectively. The MFCs 126 control flow of gases from the gas sources 122 to a manifold 128 where the gases mix. An output of the manifold 128 is supplied via an optional pressure regulator 132 to a gas distribution device, such as a showerhead 140. The showerhead 140 may be a single or multiple injection showerhead.

The substrate support 104 may also be referred to as a pedestal. The substrate support 104 may be configured to function as an ESC. For example, the substrate support 104 may include one or more ESC electrodes, such as 144.

In some examples, a temperature of the substrate support 104 may be controlled using a heater layer, such as including heaters 160. Examples of the heaters 160 include resistive heaters and other types of heaters. The substrate support 104 may include coolant channels 164. Cooling fluid is supplied to the coolant channels 164 from a fluid storage 168 and a pump 170. A pressure sensor 172 may be arranged in the manifold 128 to measure pressure within the manifold 128. A valve 178 and a pump 180 may be used to evacuate reactants from the processing chamber 108 and/or to control pressure within the processing chamber 108.

A controller 182 includes a dose controller 184 that controls dosing of gases provided by the showerhead 140. The controller 182 also controls gas delivery from the gas delivery system 120. The controller 182 controls pressure in the processing chamber and/or evacuation of reactants using the valve 178 and the pump 180.

The controller 182 also controls the temperature of the substrate support 104 and the substrate 112 based upon temperature feedback (e.g., from sensors (not shown) in the substrate support 104 and/or sensors (not shown) measuring coolant temperature). The controller 182 controls application of power to the electrode(s) 144, such as to electrostatically clamp the substrate 112 to the substrate support 104.

In some examples, the substrate processing system 100 may be configured to perform deposition of one or more materials on the substrate 112. For example, the substrate processing system 100 may be configured to deposit an ashable hard mask (AHM) on the substrate 112 using plasma enhanced chemical vapor deposition (PECVD). While the example of deposition of an AHM is provided, the present application is also applicable to other materials and other processes.

In some examples, the substrate processing system 100 may be configured to perform etching on the substrate 112 within the same processing chamber 108. Accordingly, the substrate processing system 100 may include an RF generating system 188 configured to generate and provide RF power (e.g., as a voltage source, current source, etc.) to a lower electrode (e.g., a baseplate of the substrate support 104, as shown) and an upper electrode (e.g., the showerhead 140). For example purposes only, the output of the RF generating system 188 will be described herein as an RF voltage.

The lower electrode and the upper electrode may be DC grounded, AC grounded or floating. For example, the RF generating system 188 may include an RF generator 192 configured to generate the RF voltage that is fed by a matching and distribution network 196 to generate plasma within the processing chamber 108 to etch the substrate 112. In other examples, the plasma may be generated inductively or remotely. Although, as shown for example purposes, the RF generating system 188 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

Referring now to FIGS. 1 and 2, a pedestal actuator 204 is configured to raise and lower the substrate support 104. The controller 182 may control the raising and lowering of the substrate support 104 via the pedestal actuator 204. The controller 182 may actuate the substrate support 104 via the pedestal actuator 204 such that a distance between the upper surface of substrate support 104 and the lower surface of the showerhead 140 is a target distance. The controller 182 may set the target distance within a range, for example, approximately 0.5 inches (1.27 centimeters (cm)) to 1.5 inches (3.81 cm) or another suitable range. The controller 182 may vary the target distance, for example, for loading and unloading of substrates, processing, etc.

A pin actuator 208 is configured to raise and lower substrates on the substrate support 104. For example, the pin actuator 208 includes a shaft 212 that is connected to a pin ring 216. The pin ring 216 includes three or more pins 220 that extend through apertures, respectively, through the substrate support 104. The pins 220 may be permanently fixed to the pin ring 216 or removably fixed to the ring 216 such that the pins 220 can be removed (e.g., for replacement). While the example of three pins is provided, the present application is also applicable to a greater number of pins.

The controller 182 controls actuation of the pin actuator 208 and therefore the position of the pins 220. The pin actuator 208 may actuate the pins 220 to two discrete positions relative to the substrate support 104. FIG. 1 illustrates the pins 220 being in a first (lowered) position where the substrate 112 rests on a ring 224 of the substrate support 104. In the first position, the pins 220 may be a distance below the bottom surface of the substrate 112 and not contact the substrate 112. FIG. 2 illustrates the pins 220 being in a second (raised) position where the substrate 112 is vertically lifted by the pins 220 away from the substrate support 104. The controller 182 may actuate the pins 220 via the pin actuator 208 to the second position, for example, for substrate transfer, such as to the substrate support, to a different substrate support, or out of the substrate processing system (e.g., into a different substrate processing system).

When raising and lowering the substrate support 104 via the pedestal actuator 204, the controller 182 may concurrently raise and lower, respectively, the pins 220 such that the pins 220 maintain the same position relative to the substrate support 104 despite the raising and lowering of the substrate support 104.

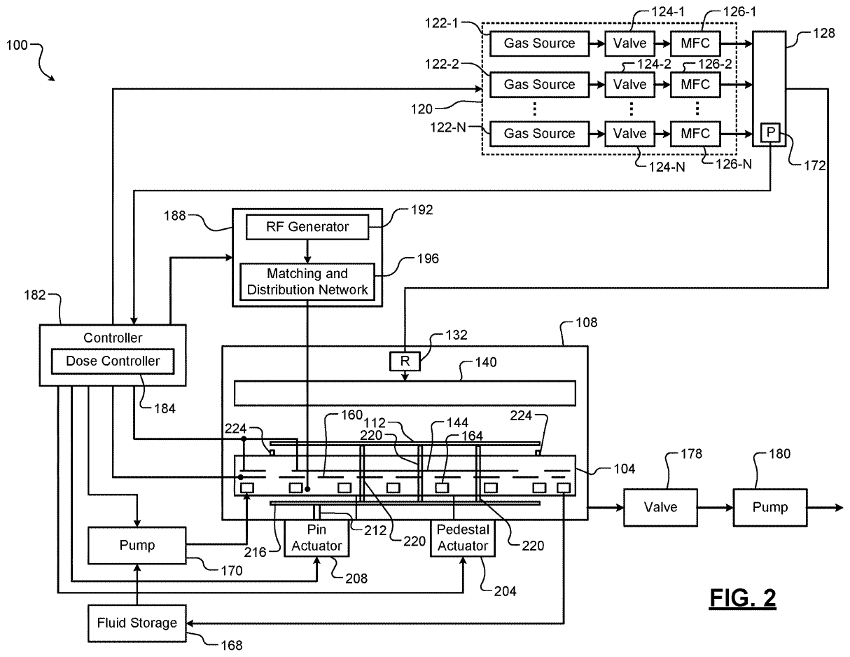

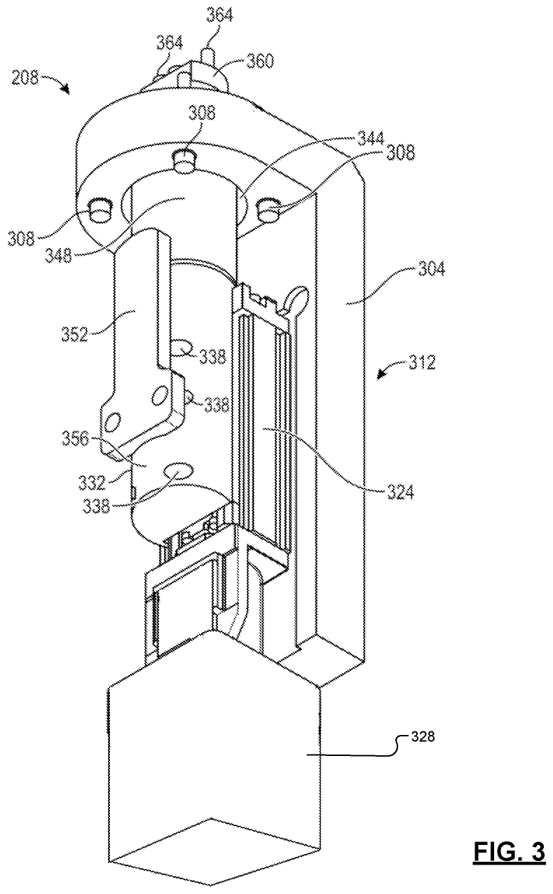

FIG. 3 is a profile view of an example implementation of the pin actuator 208. FIG. 4 is a cross-sectional view of an example implementation of the pin actuator 208. The pin actuator 208 includes a bracket 304 via which the pin actuator 208 is fastened to the processing chamber 108 by one or more fasteners, such as 308. The bracket 304 may be L-shaped, such as shown in the example of FIG. 4. More specifically, the bracket 304 may include a first portion 305 and a second portion 306 that is perpendicular to the first portion 305. The second portion 306 and a ring 307 may abut a lower portion of the processing chamber 108. One or more O-rings may be disposed between the ring 307 and the processing chamber 108 and/or between the second portion 306 and the processing chamber 108, such as to seal the processing chamber 108.

The pin actuator 208 includes a linear actuator 312. The linear actuator 312 may include, for example, a lead screw 316 and one or more pillow blocks 320 that move vertically upward when the lead screw 316 rotates in a first direction and vertically downward when the lead screw 316 rotates in a second direction opposite the first direction. The pillow block(s) 320 may include threaded apertures through which the lead screw 316 extends. The pillow blocks 320 may move vertically within a track 324.

An electric motor 328 rotates the lead screw 316. The controller 182 controls rotation of the lead screw 316 via the electric motor 328. In this manner, the controller 182 controls the position of the pins 220.

A lower bellows 332 is fixed to the pillow block(s) 320. For example, the lower bellows 332 may be fastened to the pillow block(s) 320 via fasteners (e.g., bolts) that extend through apertures 338 through the lower bellows 332. In this manner, the lower bellows 332 moves vertically with the pillow block(s) 320.

The shaft 212 is connected to the lower bellows 332. In this manner, the shaft 212 moves vertically with the lower bellows 332. For example, the shaft 212 may be fastened to the lower bellows 332 via threads formed on an outer surface of the shaft 212 and threads formed on an inner surface of the lower bellows 332. The shaft 212 extends through an aperture 344 through the second portion 306 of the bracket 304.

A folded bellows 348 surrounds the shaft 212. The folded bellows 348 extends from the lower bellows 332 to the ring 307. The folded bellows 348 vertically compresses (i.e., decreases in vertical height) as the lower bellows 332 moves vertically upward. The folded bellows 348 vertically extends (i.e., increases in vertical height) as the lower bellows 332 moves vertically downward.

The controller 182 is configured to limit a vertically upward most position of the pins 220 to the second (raised) position. A hard stop 352 is coupled to the lower bellows 332 and vertically limits the pins 220 to a third position that is vertically higher than the second position. If the pins 220 traveled vertically higher than the third position, the pin ring 216 could contact the bottom surface of the substrate support 104 and/or the pins 220 or a substrate could contact the bottom surface of the showerhead 140. This could cause damage to at least one of the substrate support, the pin ring 216, one or more of the pins 220, the showerhead 140, and the substrate 112.

The hard stop 352 directly contacts the lower surface of the second portion 306 of the bracket 304. The pins 220 are in the third position when the hard stop 352 directly contacts the lower surface of the second portion 306 of the bracket 304. Torque and/or current of the electric motor 328 increases when the hard stop 352 directly contacts the lower surface of the second portion 306 of the bracket 304 while the electric motor 328 is attempting to vertically raise the pins 220. A torque sensor may measure the torque of the electric motor 328, and a current sensor may measure the current through the electric motor 328. In various implementations, the torque of the electric motor 328 may be estimated based on one or more operating parameters. The controller 182 may control (e.g., not apply power to) the electric motor 328 when at least one of the torque and the current is greater than a torque value and a current value. The torque value and the current value are calibrated and have magnitudes that are greater than zero and correspond to the hard stop 352 directly contacting the bracket 304.

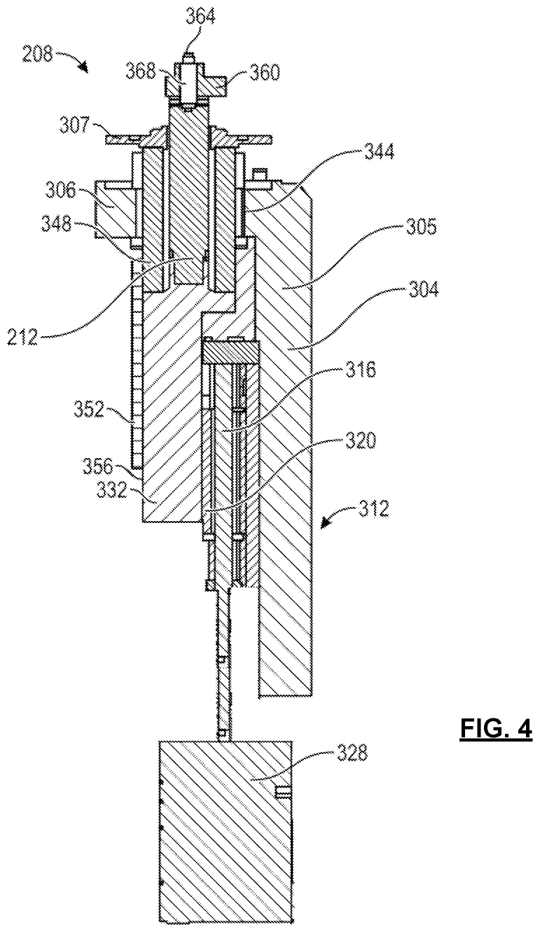

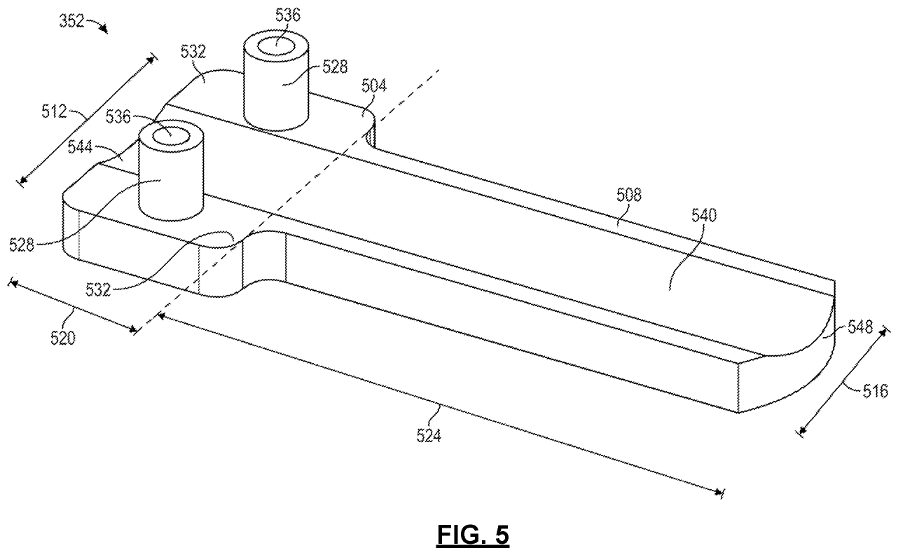

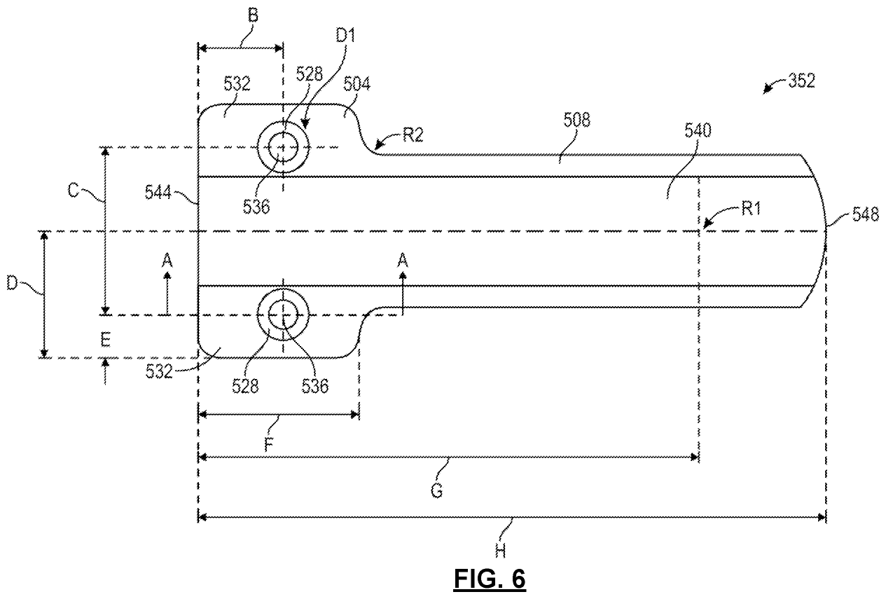

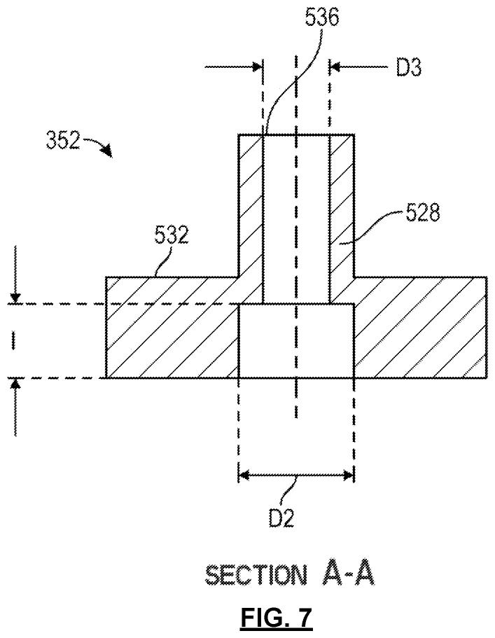

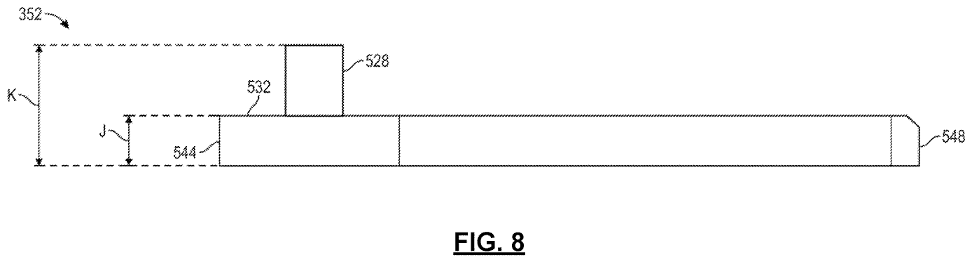

FIG. 5 is a perspective view of an example implementation of the hard stop 352. FIG. 6 is a top view toward an inner portion of the hard stop 352 that faces and part of which directly contacts the lower bellows 332. FIG. 7 is a cross-sectional view taken along line A-A of FIG. 6. FIG. 8 is a side view of the hard stop 352. FIG. 9 is an end view of the hard stop 352. The hard stop 352 may be made of stainless steel 17-4 PH or another suitable material. The hard stop 352 may be annealed.

As shown in FIGS. 5 and 6, the hard stop 352 may include a first portion 504 and a second portion 508. A width 512 of the first portion 504 may be greater than a width 516 of the second portion 508. A length 520 of the first portion 504 may be less than a length 524 of the second portion 508. Width may be expressed in a direction that is horizontal relative to the vertical movement of the shaft 212. Length may be expressed in a direction that is parallel to the vertical movement of the shaft 212.

Bosses 528 are formed on the first portion 504. The bosses 528 may be cylindrical protrusions that extend perpendicular to first surfaces 532 of the first portion 504. The bosses 528 extend into apertures in the lower bellows 332, such as shown in FIG. 3.

The bosses 528 position the hard stop 352 relative to the lower bellows 332 and provide fixation points where the hard stop 352 is fixed to the lower bellows 332. More specifically, the bosses 528 include apertures 536. The apertures 536 extend entirely through the first portion 504. Fasteners (e.g., bolts, such as M4 or M5 bolts) extend through the apertures 536 and engage threads in one or more of the pillow block(s) 320. While the example of two fasteners and bosses is provided, the hard stop 352 may include more than two bosses and/or utilize more than two fasteners. Also, while the example of the hard stop 352 coupling to one of the pillow blocks 320 is provided, the hard stop 352 may be fastened to two or more of the pillow blocks 320.

As shown in FIG. 3, the lower bellows 332 may include a longitudinally truncated cylindrical portion 356. As shown in FIGS. 5, 6, and 9, the hard stop 352 may include a concave portion 540 that extends from a first (vertically lower most) end 544 of the hard stop 352 to a second (vertically upper most) end 548 of the hard stop 352. The concave portion 540 directly contacts the longitudinally truncated cylindrical portion of the lower bellows 332. The concave portion 540 may help fix the hard stop 352 relative to the lower bellows 332. The second end 548 may directly contact the bracket 304 if the pins 220 become greater than the second (raised) position.

The second end 548 of the hard stop 352 may be rounded. Rounding the second end 548 may ensure that point contact is made with the bracket 304 even if the hard stop 352 (e.g., the concave portion 540) is not exactly parallel with the shaft 212. The second end 548 may be square in various implementations.

Example and approximate dimensions are provided below. Approximate may mean +/−10 percent. Dimensions noted with a 3 within a square are relative to a tangential point. Diameters are provided with the symbol ø. Measurement B is 0.5 inches (1.27 cm) +/−0.002 inches (0.0508 cm). Measurement C is 0.984 inches (2.499 cm) +/−0.002 inches (0.0508 cm). Measurement D is 0.75 inches (1.91 cm) +/−0.002 inches (0.0508 cm). Measurement E is 0.258 inches (0.66 cm) +/−0.002 inches (0.0508 cm). Measurement F is 0.95 inches (2.41 cm) +/−0.002 inches (0.0508 cm). Measurement G is 2.95 inches (7.49 cm) +/−0.002 inches (0.0508 cm). Measurement H is 3.7 inches (9.40 cm) +/−0.002 inches (0.0508 cm). Radius R1 is 0.75 inches (1.91 cm) +/−0.002 inches (0.0508 cm). Radius R2 is 0.15 inches (0.381 cm) +/−0.002 inches (0.0508 cm). Diameter D1 is ø 0.30 inches (0.762 cm) +/−0.005 inches (0.0127 cm). Measurement |is 0.195 inches (0.50 cm) +/−0.002 inches (0.0508 cm). Diameter D2 is φ 0.310 inches (0.762 cm) +/−0.005 inches (0.0127 cm). Diameter D3 is φ 0.17 inches (0.43 cm) +/−0.005 inches (0.0127 cm). Measurement J is 0.265 inches (0.67 cm) +/−0.002 inches (0.0508 cm). Measurement K is 0.64 inches (1.63 cm) +/−0.002 inches (0.0508 cm). Measurement L is 1.012 inches (2.57 cm) +/−0.002 inches (0.0508 cm). Measurement M is 0.30 inches (0.76 cm) +/−0.002 inches (0.0508 cm). Measurement N is 0.9 inches (2.29 cm) +/−0.002 inches (0.0508 cm). Measurement O is 0.75 inches (1.905 cm) +/−0.002 inches (0.0508 cm). Radius R3 is 0.813 inches (2.07 cm) +/−0.002 inches (0.0508 cm). The dimensions provided provide component safety and minimize a possibility of part collisions.

Referring back to FIGS. 3 and 4, the shaft 212 may include a flange 360 at a distal end of the shaft 212. One or more alignment pins 364 may extend perpendicularly to the flange 360 and parallel to the (axis of) shaft 212. While the example of two alignment pins is provided, the present application is applicable to no alignment pins and one or more alignment pins. Threads 368 may be formed within the shaft 212.

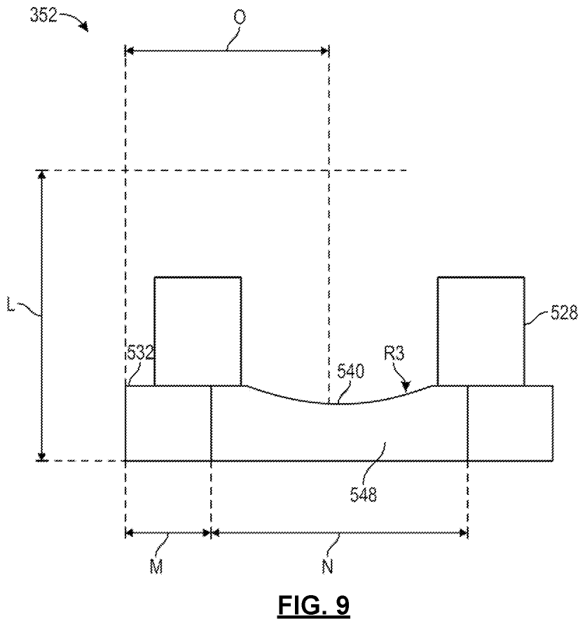

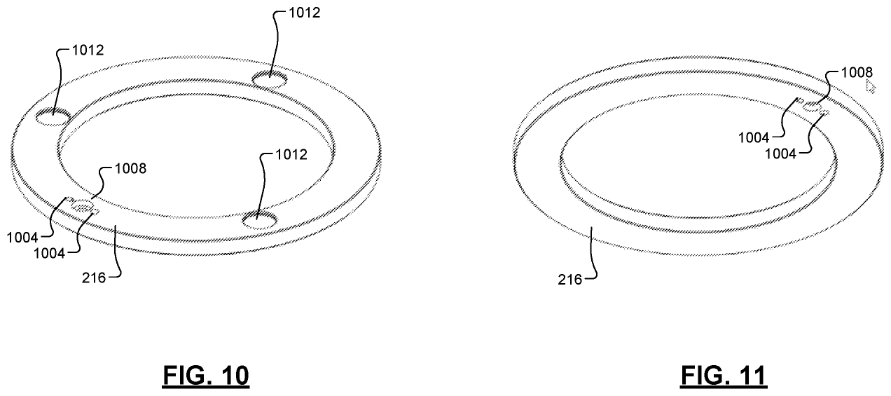

FIG. 10 includes a top perspective view of an example implementation of the pin ring 216 without the pins 220. FIG. 11 includes a bottom perspective view of the example implementation of the pin ring 216 without the pins 220.

As illustrated, the pin ring 216 may include two or more alignment apertures 1004. The pin ring 216 may have at least the same number of alignment apertures as the number of the alignment pins 364. The alignment pins 364 extend into the alignment apertures 1004.

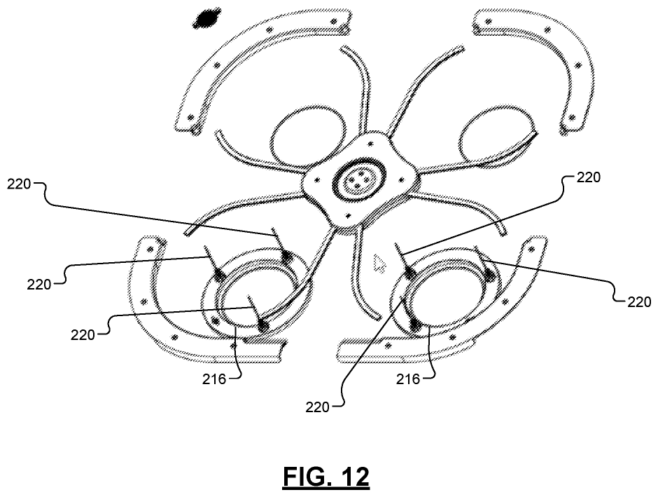

The pin ring 216 also includes a fastener aperture 1008 through which a threaded fastener (e.g., a bolt) can extend and engage the threads 368 to fasten the pin ring 216 to the pin actuator 208. The pin ring 216 includes pin apertures 1012 to which the pins 220 can be fastened. For example, the pins 220 and the pin apertures 1012 may be threaded, and the pins 220 may be fastened to the pin apertures 1012 via the threads. In various implementations, the pins 220 may be permanently fixed to the pin ring 216. FIG. 12 is a perspective view including an example implementation of the processing chamber 108 for multiple substrate supports, each with an instance of the pin ring 216 with the pins 220. One pin ring actuator and hard stop is provided with each pin ring.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, pin actuation, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, perform cleaning operations, perform endpoint measurements, perform pin actuation/movement, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A hard stop for a substrate processing system, the hard stop comprising:
a first portion including:
bosses configured to extend into first apertures in a lower bellows of a pin actuator;
second apertures extending through the bosses, respectively, and the first portion; and
a second portion including:
a first end that is connected to the first portion; and
a second end configured to contact a bracket of the pin actuator, the bracket configured to mount the pin actuator to a substrate processing chamber.

2. The hard stop of claim 1 wherein:
the bosses include two bosses; and
the second apertures include two second apertures extending through the two bosses, respectively, and the first portion.

3. The hard stop of claim 1 wherein the first and second portions are made of stainless steel.

4. The hard stop of claim 1 wherein the first and second portions are made of 17-4 PH stainless steel.

5. The hard stop of claim 4 wherein the 17-4 PH stainless steel is annealed.

6. The hard stop of claim 1 further comprising a concave portion that extends through the first and second portions, the concave portion configured to directly contact a cylindrical surface of the lower bellows of the pin actuator.

7. The hard stop of claim 1 wherein the second end of the second portion is rounded.

8. A pin actuator for a substrate processing system, the pin actuator comprising:
a lead screw configured to:
linearly move a pillow block in a first direction in response to rotation of the lead screw in the first direction; and
linearly move the pillow block in a second direction that is opposite the first direction in response to rotation of the lead screw in the second direction;
the pillow block;
a lower bellows including apertures;
a hard stop including bosses that extend into the apertures in the lower bellows; and
fasteners that fasten the hard stop and the lower bellows to the pillow block.

9. The pin actuator of claim 8 further comprising a bracket configured to mount the pin actuator to a substrate processing chamber, wherein the hard stop is disposed to contact a surface of the bracket.

10. The pin actuator of claim 9 wherein the bracket includes:
a first portion, wherein a track within which the pillow block moves is coupled to the first portion; and
a second portion that is perpendicular to the first portion and that is to mount the pin actuator to the substrate processing chamber.

11. The pin actuator of claim 10 further comprising a shaft coupled at a first end to the lower bellows and configured to couple at a second end to a pin ring, the pin ring configured to vertically raise and lower a substrate within the substrate processing chamber via pins of the pin ring.

12. The pin actuator of claim 11 further comprising a folded bellows that surrounds the shaft.

13. The pin actuator of claim 11 wherein the shaft extends through an aperture in the second portion of the bracket.

14. The pin actuator of claim 9 wherein the hard stop includes a rounded edge configured to contact the surface of the bracket.

15. The pin actuator of claim 7 wherein:
the lower bellows includes a cylindrical outer surface; and
the hard stop includes a concave portion that directly contacts the cylindrical outer surface of the lower bellows.

16. A substrate processing system, comprising:
a processing chamber;
a substrate support within the processing chamber, the substrate support to support substrates on an upper surface thereof;
a pin ring including at least three pins that extend through apertures through the substrate support, the pins configured to vertically lower a substrate onto the upper surface of the substrate support and to vertically raise the substrate above the upper surface of the substrate support;
a pin actuator configured to vertically raise and lower the pin ring, thereby vertically raising and lowering the at least three pins, respectively;
a bracket configured to mount the pin actuator to the processing chamber; and
a hard stop including bosses that extend into apertures in the pin actuator and that is mounted to the pin actuator, the hard stop configured to contact a surface of the bracket and limit a vertical height of the at least three pins relative to the substrate support to a maximum height.

17. The substrate processing system of claim 16, wherein the pin actuator includes:
a lead screw configured to:
linearly move a pillow block in a first direction in response to rotation of the lead screw in the first direction; and
linearly move the pillow block in a second direction that is opposite the first direction in response to rotation of the lead screw in the second direction;
the pillow block;
a lower bellows including the apertures; and
fasteners that fasten the hard stop and the lower bellows to the pillow block.

18. The substrate processing system of claim 16 wherein the hard stop incudes:
a first portion including:
the bosses;
second apertures through the bosses, respectively, and the first portion; and
a second portion including:
a first end that is connected to the first portion; and
a second end configured to contact the surface of the bracket.

19. The substrate processing system of claim 18 wherein the hard stop further includes a concave portion that extends through the first and second portions, the concave portion directly contacting a cylindrical surface of the pin actuator.

20. The substrate processing system of claim 18 wherein the second end of the second portion is rounded.
